(19) United States
(12) Patent Application Publication
(10) Pub. No.: US 2026/0341656 A1
(43) Pub. Date: Oct. 29, 2026

(54) PLASMA CONTROL SYSTEM AND PLASMA CONTROL METHOD

(71) Applicant: Rohde & Schwarz GmbH & Co. KG, Muenchen (DE)

(72) Inventor: Mathias PIETZKA, Muenchen (DE)

(21) Appl. No.: 19/193,474

(22) Filed: Apr. 29, 2025

(51) Int. Cl. H01J 37/32

(52) U.S. Cl. CPC H01J 37/32944; H01J 37/32183; H01J 37/32926; H01J 2237/24564

(57) ABSTRACT

A plasma control system and a the plasma control method are described that provide an optimized control of an operational state of plasma. The operational state of the plasma is detected based on the first detector signal and based on the second detector signal plugged into a mathematical model of the plasma. Depending on the operational state detected, the control circuit appropriately controls the RF generator circuit and/or the impedance matching network.

### FIELD OF THE DISCLOSURE

Embodiments of the present disclosure generally relate to a plasma control system. Embodiments of the present disclosure further relate to a plasma control method.

### BACKGROUND

The generation of low-temperature plasma is often realized by applying RF power into a gas filled process chamber, such that the gas atoms are ionized and a plasma is established. Such plasmas are, for example, utilized for plasma processes such as plasma etching of wafers, or plasma deposition on wafers or other workpieces.

The ignition and maintenance of the plasma requires a matching of the RF source impedance to the plasma impedance, which can be within a large impedance range depending on gas type, process chemistry, etc. For this purpose, an impedance matching network is placed into the RF chain between the RF signal generator and the process chamber.

Due to equipment malfunctions, improper parameter settings, or issues with materials being used, electrical arcs can form in the plasma, which may lead to suboptimal plasma process results or even damage to the workpiece.

Accordingly, there is a need for a plasma control system and a plasma control method that allow for a more optimal control of plasma processes.

### SUMMARY

The following summary of the present disclosure is intended to introduce different concepts in a simplified form that are described in further detail in the detailed description provided below. This summary is neither intended to denote essential features of the present disclosure nor shall this summary be used as an aid in determining the scope of the claimed subject matter.

Embodiments of the present disclosure provide a plasma control system. In an embodiment, the plasma control system comprises an impedance matching network, a radio frequency (RF) generator circuit, a chamber feed unit, and a control circuit. The RF generator circuit is configured to generate an RF signal. The chamber feed unit is configured to feed energy into plasma. An input port of the impedance matching network is connected to the RF generator circuit, and an output port of the impedance matching network is connected to the chamber feed unit.

In this or other embodiments, the plasma control system further comprises a first detector circuit that is arranged between the RF generator circuit and the impedance matching network, wherein an RF output of the first detector circuit is connected to the impedance matching network. The first detector circuit is configured to generate a first detector signal associated with the RF signal upstream of the impedance matching network.

In this or other embodiments, the plasma control system further comprises a second detector circuit, wherein the second detector circuit is arranged between the impedance matching network and the chamber feed unit. The second detector circuit is configured to generate a second detector signal associated with the RF signal downstream of the impedance matching network.

In this or other embodiments, the control circuit is configured to detect at least one operational state of the plasma based on the first detector signal, based on the second detector signal, and based on a mathematical model of the plasma.

The term “mathematical model” is understood to denote a set of equations and/or conventional algorithms that describe a physical replacement model of the plasma. Accordingly, the term “mathematical model” does not comprise machine-learning based approaches, such as deep-learning based neural networks.

The plasma control system according to the present disclosure is based on the idea to use a mathematical model of the plasma in order to more closely monitor an operational state of the plasma.

Typically, there are no or only few plasma sensors arranged in the plasma chamber that can measure state parameters of the plasma directly. Thus, it may be not possible to assess the operational state of the plasma based on sensor signals of these plasma sensors alone.

To address these drawbacks, a mathematical model is utilized to determine state parameters of the plasma, which cannot be measured based on available detector signals, namely based on the first detector signal and based on the second detector signal. Accordingly, the mathematical model is comparable to or may be a state observer (also called state estimator or Luenberger observer) according to control theory.

Generally speaking, the mathematical model of the plasma generally describes the operational state or state parameters of the plasma in dependence of the RF signal applied to the plasma, namely in dependence of the first detector signal and the second detector signal. By monitoring the operational state of the plasma, certain operational states of the plasma can be detected by the control circuit, and operational parameters of the plasma control system can be adapted, if necessary.

The inventors of the subject matter disclosed herein have discovered that use of the mathematical model allows for detection of the operational state of the plasma and for adaptation of the operational parameters of the plasma control system in a particular precise and fast manner, while also being simple to implement.

For example, the fast detection of the operational state of the plasma allows, for example, to detect short events like micro-arcs. In use herein, the term “arc” is understood to denote a sudden discharge of energy between the chamber feed unit and another component in the plasma chamber, for example a housing of the plasma chamber or a workpiece in the plasma chamber. The arc may correspond to a direct current.

Moreover, the inventors of the subject matter disclosed herein have discovered that the plasma control system according to embodiments of the present disclosure is particularly resistant against measurement artifacts, i.e. against measurement errors introduced by, for example, the first detector circuit and/or the second detector circuit. This allows for particularly precise control of the operational state of the plasma.

For example, mis-control of operational parameters of the plasma control system is reliably avoided, for example a too early or too late muting of the RF generator circuit, or a too long or too short muting of the RF generator circuit.

In one or more embodiments, the plasma control system employ a mathematical model that is considerably less complex than, for example, neural networks that are trained to monitor the plasma, which makes the plasma control system according to various embodiments the present disclosure easier to implement. Moreover, compared to a machine-learning based solution, the plasma control system according to these various embodiments of the present disclosure requires less computational resources.

In an embodiment, the operational states detectable by the control circuit may comprise at least one of a nominal operational state, an irregular operational state, or a critical operational state.

In an embodiment, the nominal operational state generally corresponds to a desired operational state of the plasma, i.e. most or all state parameters of the plasma are within a desired, nominal range.

In an embodiment, the irregular operational state may correspond to an operational state wherein at least one state parameter or several operational parameters of the plasma may be outside of the desired, nominal range. The irregular operational state may require tuning of operational parameters of the plasma control system, but the tuning of the parameters may not be time-critical.

In an embodiment, the critical operational state may correspond to an operational state wherein at least one state parameter or several operational parameters of the plasma may be outside of the desired, nominal range. The critical operational state may require timely tuning of operational parameters of the plasma control system, i.e. the tuning of the parameters may be time-critical.

Summarizing, the plasma control system in its various implementations allows for an optimized control of plasma processes, as the operational state of the plasma can be determined by, for example, the first detector signal, the second detector signal, and/or the mathematical model. This allows for a precise and fast control of operational parameters of the plasma control system, as will be described in more detail below.

According to an aspect of the present disclosure, the control circuit, for example, is configured to detect at least one arc evolving in the plasma based on the first detector signal, based on the second detector signal, and/or based on the mathematical model of the plasma. In an embodiment, the detection of an arc may correspond to detecting a critical operational state of the plasma, as the arc can lead to suboptimal plasma process results or even to damage to a workpiece. With the plasma control system according to the present disclosure, arcs can be detected in a reliable and fast manner, and timely countermeasures can be taken if necessary.

In an example embodiment, the first detector circuit comprises a coupling circuit. In general, the coupling circuit is configured to forward the RF signal received from the RF generator circuit to the impedance matching network. Moreover, the coupling circuit may be configured to forward the RF signal to the control circuit. For example, the coupling circuit may comprise a directional coupler circuit.

In an embodiment, the sensors for acquiring the first detector signal may be integrated into the coupling circuit, for example into the directional coupler circuit. Thus, no additional sensor are required, thereby reducing the manufacturing costs and complexity of the plasma control system.

According to another aspect of the present disclosure, the second detector circuit, for example, comprises a measurement probe, for example a voltage-current probe (V/I probe). Accordingly, the second detector circuit may be configured to measure both a voltage and a current associated with the RF signal downstream of the impedance matching network. Moreover, the second detector circuit may be configured to measure a phase between the voltage and the current, a power level of the RF signal, and/or a momentary impedance. However, it is to be understood that the second detector circuit may comprise or be established as any other suitable type of detector(s) or sensor(s).

In another embodiment, the first detector signal comprises an amplitude of a first RF voltage associated with the RF signal upstream of the impedance matching network, an amplitude of a first RF current associated with the RF signal upstream of the impedance matching network, and a phase between the first RF voltage and the first RF current. The inventors of the disclosed subject matter have discovered that the operational state of the plasma can be precisely monitored based on these quantities alone.

In an embodiment, the first detector circuit may have a sample rate that is greater than or equal to a first predetermined sample rate. For example, the first predetermined sample rate may be 100 kHz, 1 MHz, 10 MHz, or 100 MHz.

In general, the sample rate of the first detector circuit may be chosen such that the phase between the first RF voltage and the first RF current can be evaluated accurately.

An aspect of the present disclosure provides that the second detector signal comprises, for example, an amplitude of a second RF voltage associated with the RF signal downstream of the impedance matching network, an amplitude of a second RF current associated with the RF signal downstream of the impedance matching network, and a phase between the second RF voltage and the second RF current. The inventors of the disclosed subject matter have discovered that the operational state of the plasma can be precisely monitored base on these quantities alone.

In an embodiment, the second detector circuit may have a sample rate that is greater than or equal to a second predetermined sample rate. For example, the second predetermined sample rate may be 100 kHz, 1 MHz, 10 MHz, or 100 MHz.

In general, the sample rate of the second detector circuit may be chosen such that the phase between the second RF voltage and the second RF current can be evaluated accurately.

According to another aspect of the present disclosure, the control circuit, for example, is configured to control the RF generator circuit based on the at least one detected operational state. Accordingly, if the detected operational state of the plasma requires a change of the operational parameters of the plasma control system, the control circuit may control the RF generator circuit to adapts its operational parameters.

For example, the control circuit is configured to control the RF generator circuit to adapt at least one signal parameter of the RF signal generated. Accordingly, the operational state of the plasma may at least partially be controlled by adapting the at least one signal parameter of the RF signal generated by the RF generator circuit.

In an embodiment, the at least one signal parameter may comprise an amplitude, a phase, a power level, a frequency, and/or a signal shape. However, it is to be understood that the at least one signal parameter may comprise any other suitable signal parameter.

As another example, the control circuit is configured to temporarily deactivate the RF generator circuit if the at least one detected operational state comprises at least one arc. By temporarily deactivating the RF generator circuit, the arc is extinguished, as no further power is transferred into the plasma. Thus, damage to a workpiece inside the plasma chamber is reliably avoided, as the plasma control system according to the present disclosure allows for detecting arcs in a particularly fast and reliable manner.

A further aspect of the present disclosure provides, for example, that the control circuit is configured to control the impedance matching network based on the at least one detected operational state. Accordingly, the operational state of the plasma may at least partially be controlled by adapting operational parameters of the impedance matching network.

In an embodiment, the control circuit may be configured to control the impedance matching network to adapt its impedance. Accordingly, the operational state of the plasma may at least partially be controlled by adapting the impedance of the impedance matching network.

In another embodiment, the mathematical model describes a sheath in the plasma. In general, due to the RF signal applied to the chamber feed unit, a space charge is formed by ions near the chamber feed unit, which space charge is called “sheath”. This sheath allows to assess the operational state of the plasma, for example with respect to arcs evolving in the plasma. However, this sheath can usually not be measured, as no corresponding sensors are provided in the plasma chamber. The mathematical model allows to reconstruct the sheath based on available detector signals, namely based on the first detector signal and based on the second detector signal.

In a further embodiment of the present disclosure, the mathematical model describes the sheath in the plasma in dependence of the RF signal fed into the plasma by the chamber feed unit. In other words, the sheath can be reconstructed based on the RF signal applied to the chamber feed unit, which can be determined based on the first detector signal and the second detector signal.

According to an aspect of the present disclosure, the control circuit, for example, is configured to compare the first detector signal and/or the second detector signal with a comparison data set in order to detect the at least one operational state of the plasma. The comparison data set comprises previously measured first detector signals and/or previously measured second detector signals. By comparing the first detector signal and/or the second detector signal with the comparison data set, conclusions about the current operational state of the plasma can be drawn, as the current detector signals usually will be similar to the previous detector signals corresponding to the same operational state.

For example, the comparison data set may comprise first detector signals and/or second detector signals that correspond to a nominal operational state of the plasma, an irregular operational state of the plasma, and/or a critical operational state of the plasma.

In a certain example, the comparison data set may comprise first detector signals and/or second detector signals that correspond to an arc evolving or being present in the plasma.

According to another aspect of the present disclosure, the RF signal generated by the RF generator circuit comprises, for example, a power portion and a reference portion. In an embodiment, the reference portion is modulated onto the power portion, and wherein the power portion and the reference portion have frequencies being different from each other. The power portion of the RF signal is intended to transfer energy into the plasma. Accordingly, an amplitude, frequency, power level etc. of the power portion may be chosen according to the power requirements and impedance requirement of the plasma. The reference portion serves as a reference signal for evaluating the first detector signal and the second detector signal, namely for detecting the operational state of the plasma based on the mathematical model.

In an embodiment, a frequency of the reference portion may be higher than a frequency of the power portion.

In an embodiment, an amplitude or power level of the reference portion may be smaller than the amplitude or power level of the power portion.

In an embodiment, the control circuit may comprise a field-programmable gate array (FPGA) or similar circuitry. This allows for the determination or detection of the at least one operational state of the plasma in a particularly fast manner.

In an example embodiment of the present disclosure, the plasma control system comprises at least one plasma sensor. The at least one plasma sensor is configured to measure at least one state parameter of the plasma. The control circuit is configured to detect the at least one operational state of the plasma based on the at least one state parameter of the plasma. In an embodiment, the at least one state parameter of the plasma may be used in order to verify the operational state detected by the control circuit based on the first detector signal, based on the second detector signal, and/or based on the mathematical model of the plasma. Thus, the reliability of the detected operational state is further increased.

For example, the at least one state parameter of the plasma may comprise a pressure, a temperature, a pressure gradient, a temperature gradient, a change of the pressure over time, and/or a change of the temperature over time. However, it is to be understood that the at least one state parameter may comprise any other suitable type of parameter.

A further aspect of the present disclosure provides that the RF generator circuit, for example, is configured to provide at least one state parameter of the RF generator circuit. In an embodiment, the control circuit is configured to detect the at least one operational state of the plasma based on the at least one state parameter of the RF generator circuit. In an embodiment, the at least one state parameter of the RF generator circuit may be used in order to verify the operational state detected by the control circuit based on the first detector signal, based on the second detector signal, and based on the mathematical model of the plasma. Thus, the reliability of the detected operational state is further increased.

Embodiments of the present disclosure further provide a plasma control method. In an embodiment, the plasma control method comprises the steps of generating, by an RF generator circuit, at least one RF signal; processing, by at least one impedance matching network, the at least one RF signal, thereby obtaining at least one output signal; feeding the at least one output signal to at least one chamber feed unit; generating, by a first detector circuit being arranged between the between the RF generator circuit and the impedance matching network, a first detector signal associated with the RF signal upstream of the impedance matching network; generating, by a second detector circuit being arranged between the impedance matching network and the chamber feed unit, a second detector signal associated with the RF signal downstream of the impedance matching network; and detecting, by a control circuit, at least one operational state of the plasma based on the first detector signal, based on the second detector signal, and based on a mathematical model of the plasma.

In an embodiment, the plasma control system according to any one of the embodiments described above is configured to perform the plasma control method.

Regarding the further advantages and properties of the plasma control method, reference is made to the explanations given above with respect to the plasma control system, which also hold for the plasma control method and vice versa.

In an embodiment, at least one arc evolving in the plasma is detected based on the first detector signal, based on the second detector signal, and based on the mathematical model of the plasma. The detection of an arc may correspond to detecting a critical operational state of the plasma, as the arc can lead to suboptimal plasma process results or even to damage to a workpiece. With the plasma control method according to the present disclosure, arcs can be detected in a reliable and fast manner, and timely countermeasures can be taken if necessary.

### DESCRIPTION OF THE DRAWINGS

The foregoing aspects and many of the attendant advantages of the claimed subject matter will become more readily appreciated as the same become better understood by reference to the following detailed description, when taken in conjunction with the accompanying drawings, wherein:

FIG. 1 schematically shows a plasma control system according to an embodiment of the present disclosure;

FIG. 2 schematically shows an embodiment of an impedance matching network of the plasma control system of FIG. 1;

FIG. 3 shows a representative flow chart of a plasma control method according to an embodiment of the present disclosure;

FIG. 4 schematically illustrates an RF signal generated by an RF generator circuit of the plasma control system of FIG. 1; and

FIG. 5 illustrates an example of a mathematical model that can be used in the plasma control method of FIG. 3.

### DETAILED DESCRIPTION

The detailed description set forth below in connection with the appended drawings, where like numerals reference like elements, is intended as a description of various embodiments of the disclosed subject matter and is not intended to represent the only embodiments. Each embodiment described in this disclosure is provided merely as an example or illustration and should not be construed as preferred or advantageous over other embodiments. The illustrative examples provided herein are not intended to be exhaustive or to limit the claimed subject matter to the precise forms disclosed.

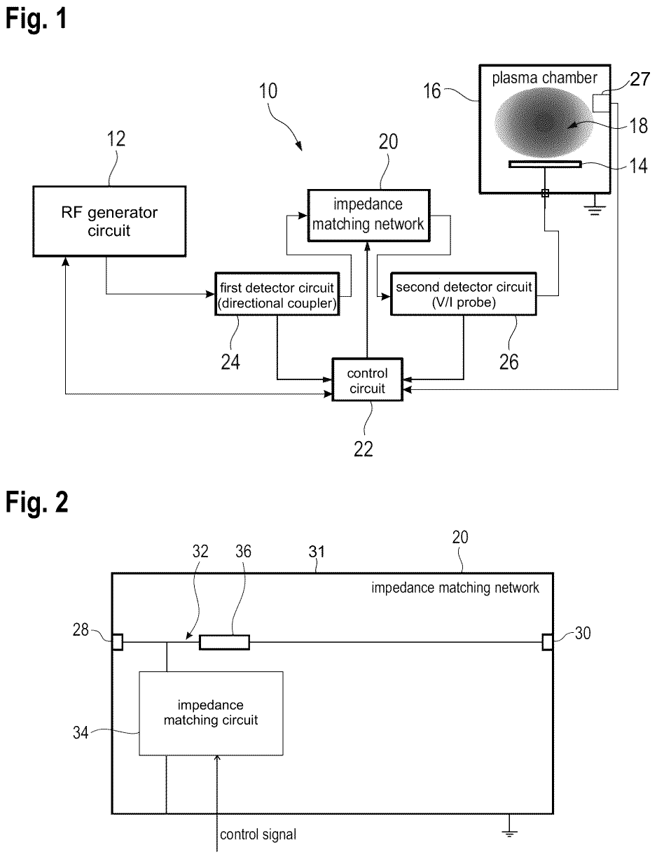

FIG. 1 schematically shows an example of a plasma control system 10 that comprises an RF generator circuit 12 and a chamber feed unit 14. The chamber feed unit 14 is located in a plasma chamber 16. In general, the RF generator circuit 12 is configured to generate an RF signal that is forwarded to the chamber feed unit 14. The chamber feed unit 14 feeds the RF signal into plasma 18 contained in the plasma chamber 16, thereby initiating and/or maintaining the plasma 18. For example, the chamber feed unit 14 may be an electrode generating an electric field or an inductive coil generating a magnetic field.

In order to minimize losses and maximize the amount of energy fed into the plasma 18, the plasma control system 10 comprises an impedance matching network 20. The impedance of the impedance matching network 20 can be adapted in order to account for a varying impedance of the plasma 18. In the embodiment shown, the impedance matching network 20 is interconnected between the RF generator circuit 12 and the chamber feed unit 14 such that the impedance of a load presented to the RF generator circuit 12 can be adapted by the impedance matching network 20.

The impedance of the impedance matching network 20 is controlled by a control circuit 22. For example, the control circuit may comprise or be established as a field-programmable gate array (FPGA) or similar circuitry.

In an embodiment, the control circuit 22 may control the impedance matching network 20 based on at least one first detector signal obtained by a first detector circuit 24, and based on at least one second detector signal obtained by a second detector circuit 26.

The first detector circuit 24 is interconnected between the RF generator circuit 12 and the impedance matching network 20. An RF input port of the first detector circuit 24 is connected to the RF generator circuit 12, and an RF output port of the first detector circuit 24 is connected to the impedance matching network 20. Thus, an input signal of the impedance matching network 20 corresponds to the RF signal generated by the RF generator circuit 12.

In the embodiment shown, the first detector circuit 24 is also connected to the control circuit 22, such that the first detector signal obtained by the first detector circuit 24 is forwarded to the control circuit 22. As is indicated in FIG. 1, the first detector circuit 24 may be established as or comprise a directional coupler circuit.

In the embodiment shown, the second detector circuit 26 is interconnected between the impedance matching network 20 and the chamber feed unit 14. In an embodiment, an RF input port of the second detector circuit 26 is connected to the impedance matching network 20, and an RF output port of the second detector circuit 26 is connected to the chamber feed unit 14. Moreover, the second detector circuit 26 is connected to the control circuit 22, such that the second detector signal obtained by the second detector circuit 26 is forwarded to the control circuit 22.

In an embodiment, the first detector circuit 24 may be established as or comprise a voltage-current probe (V/I probe).

Optionally, the plasma control system 10 may further comprise at least one plasma sensor 27 that is provided within the plasma chamber 16. In general, the optional at least one plasma sensor 27 may be configured to measure at least one state parameter of the plasma 18, wherein the at least one plasma sensor 27 is connected to the control circuit 22 and configured to forward the at least one state parameter of the plasma 18 to the control circuit 22.

In an embodiment, the at least one state parameter of the plasma 18 may comprise a pressure, a temperature, a pressure gradient, a temperature gradient, a change of the pressure over time, and/or a change of the temperature over time.

FIG. 2 schematically shows an example embodiment of the impedance matching network 20 in more detail. The impedance matching network 20 comprises an input port 28 that is connected to the RF generator circuit 12 or to the first detector circuit 24. The impedance matching network 20 further comprises an output port 30 that is connected to the chamber feed unit 14 or to the second detector circuit 26. In an embodiment, the impedance matching network 20 may comprise a housing 31, wherein the input port 28 and the output port 30 may be provided in a wall or in walls of the housing 31.

Between the input port 28 and the output port 30, a transmission circuit having a transmission line 32 is provided that connects the input port 28 to the output port 30.

In general, the impedance matching network 20 is configured to forward the RF signal generated by the RF generator circuit 12 from the input port 28 to the output port 30 while matching an impedance presented to the RF generator circuit 12.

In an embodiment, the impedance matching network 20 comprises an impedance matching circuit 34. In general, the impedance matching circuit 34 is configured to selectively couple at least one reactance to and/or into the transmission line 32, thereby adapting an impedance of the impedance matching network 20.

In an embodiment, the at least one reactance may comprise at least one capacitance and/or at least one inductance. For example, the at least one reactance may comprise a plurality of capacitances and/or a plurality of inductances.

In the e embodiment shown in FIG. 2, the impedance matching circuit 34 is interconnected between a contact point to the transmission line 32 and a common reference potential. Accordingly, the impedance matching circuit 34 is configured to selectively couple the at least one reactance between the transmission line 32 and the common reference potential. For example, the common reference potential may be a ground potential.

However, it is to be understood that the impedance matching circuit 34 may alternatively be provided in the transmission line 32, wherein the impedance matching circuit 34 may be interconnected between the input port 28 and the output port 30.

In this case, the impedance matching circuit 34 may be configured to selectively couple the at least one reactance into the transmission line 32 between the input port 28 and the output port 30.

Moreover, it is to be understood that further impedance matching circuits may be provided in an arbitrary topology. For example, the impedance matching circuits of the impedance matching network 20 may be arranged according to a T-topology, an L-topology, or a π-topology.

In the embodiment shown, the impedance matching circuit 34 may receive a control signal from the control circuit 22, wherein the control signal controls the impedance matching circuit 34 to adapt its impedance.

In an embodiment, the impedance matching network 20 may comprise at least one further reactance 36, for example at least one further inductance, that is provided in the transmission line 32.

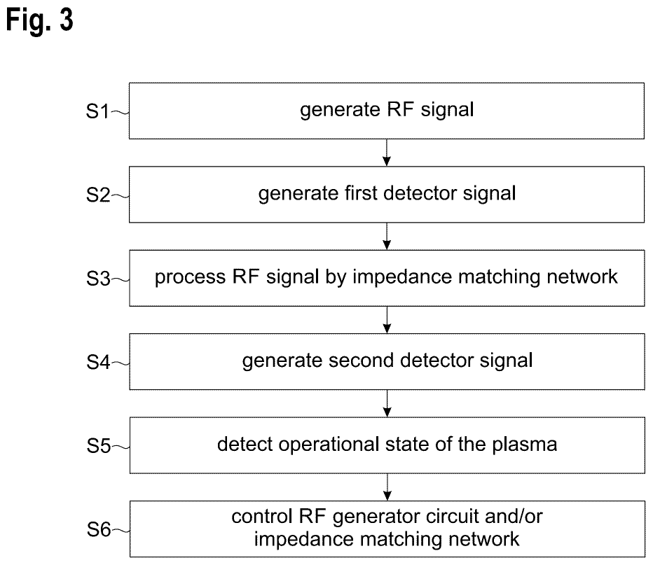

The plasma control system 10 described above is configured to perform a plasma control method, an example of which is described hereinafter with reference to FIG. 3.

An RF signal is generated by the RF generator circuit 12 (step S1).

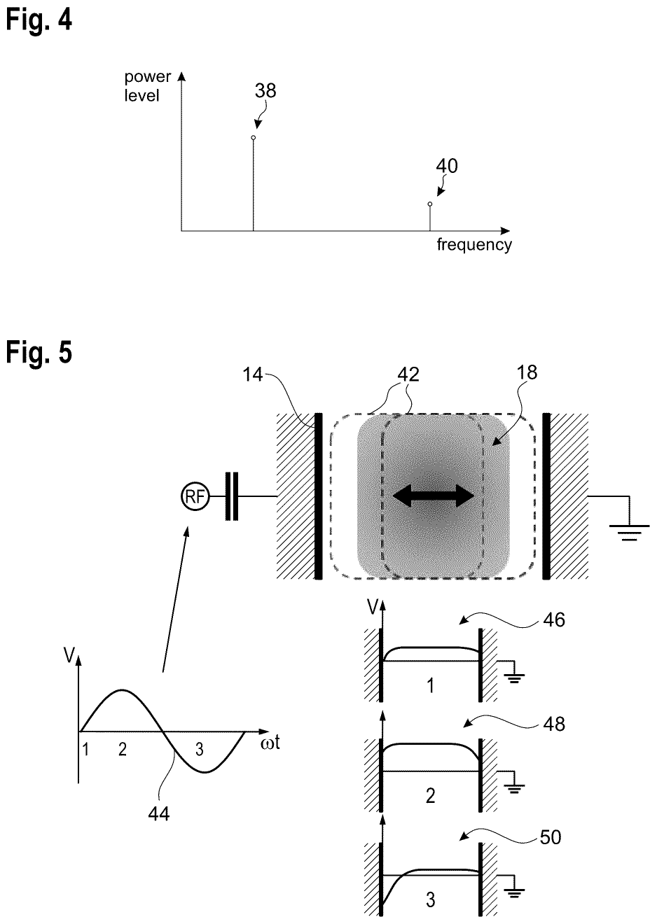

As is illustrated in FIG. 4, which schematically shows an example power spectrum of the RF signal, the RF signal may comprise a power portion 38, i.e. a portion having suitable frequency, amplitude, power level, etc., in order to transfer energy into the plasma 18. Moreover, the RF signal may comprise a reference portion 40 that is modulated onto the power portion.

In general, the reference portion 40 has a different frequency than the power portion 38, for example a higher frequency. In an embodiment, the reference portion 40 may have a frequency that is much larger than the frequency of the power portion 38, for example one or several orders of magnitude larger than the frequency of the power portion 38. Accordingly, it is to be understood that the frequency axis in FIG. 4 may be scaled logarithmically. It is also to be understood that the reference portion 40 does not have to be a harmonic of the power portion 38.

In an embodiment, an amplitude or power level of the reference portion 40 may be smaller than the amplitude or power level of the power portion 38.

The RF signal generated by the RF generator circuit 12 is forwarded to the first detector circuit 24.

A first detector signal is generated by the first detector circuit 24 based on the RF signal received from the RF generator circuit 12 (step S2).

The first detector signal comprises an amplitude of a first RF voltage associated with the RF signal upstream of the impedance matching network 20, an amplitude of a first RF current associated with the RF signal upstream of the impedance matching network 20, and a phase between the first RF voltage and the first RF current.

Optionally, the first detector signal may further comprise a power level of the RF signal upstream of the impedance matching network, and/or a momentary impedance, which corresponds to the quotient of the first RF voltage and the first RF current.

In an embodiment, the first detector circuit 24 may have a sample rate that is greater than or equal to a first predetermined sample rate, i.e. the first RF voltage, the first RF current, and/or the phase between the first RF voltage and the first RF current may be determined with that sample rate. For example, the first predetermined sample rate may be 100 kHz, 1 MHz, 10 MHz, or 100 MHz.

The first detector signal is forwarded to the control circuit 22 by the first detector circuit 24. Moreover, the RF signal is forwarded to the impedance matching network 20 by the first detector circuit 24.

The RF signal is processed by the impedance matching network 20, thereby obtaining an output signal (step S3).

The output signal corresponds to the RF signal processed by the impedance matching network 20, i.e., the RF signal is altered based on the impedance of the impedance matching network 20. The output signal is forwarded to the second detector circuit 26

A second detector signal is generated by the second detector circuit 26 based on the RF signal received from the RF generator circuit 12 (step S4).

The second detector signal comprises an amplitude of a second RF voltage associated with the RF signal downstream of the impedance matching network 20, an amplitude of a second RF current associated with the RF signal downstream of the impedance matching network 20, and a phase between the second RF voltage and the second RF current.

In an embodiment, the RF signal downstream of the impedance matching network 20 is the output signal of the impedance matching network 20.

Optionally, the second detector signal may further comprise a power level of the RF signal downstream of the impedance matching network 20, and/or a momentary impedance, which corresponds to the quotient of the second RF voltage and the second RF current.

In an embodiment, the, the second detector circuit 26 may have a sample rate that is greater than or equal to a second predetermined sample rate, i.e. the second RF voltage, the second RF current, and/or the phase between the second RF voltage and the second RF current may be determined with that sample rate. For example, the second predetermined sample rate may be 100 kHz, 1 MHz, 10 MHz, or 100 MHz.

In an embodiment, the first detector circuit 24 and the second detector circuit 26 may have the same sample rate.

The second detector signal is forwarded to the control circuit 22 by the second detector circuit 26. Moreover, the output signal of the impedance matching network 20 is forwarded to the chamber feed unit 14 by the second detector circuit 26, i.e., the output signal is fed to the chamber feed unit 14, and into the plasma 18 via the chamber feed unit 14.

At least one operational state of the plasma 18 is detected, by the control circuit 22, based on the first detector signal, based on the second detector signal, and based on a mathematical model of the plasma 18 (step S5).

Optionally, the at least one operational state may be detected (additionally) based on the at least one state parameter of the plasma 18 measured by the at least one plasma sensor 27.

As a further option, the RF generator circuit 12 may provide at least one state parameter of the RF generator circuit 12 to the control circuit 22, and the control circuit 22 may detect the at least one operational state of the plasma 18 (additionally) based on the at least one state parameter of the RF generator circuit 12.

For example, the at least one state parameter of the RF generator circuit 12 may comprise a frequency of the RF signal generated, and/or a power level of the RF signal generated, for example frequencies and/or power levels of the power portion 38 and/or the reference portion 40.

In an embodiment, the at least one operational state detected by the control circuit 22 may, for example, be a nominal operational state, an irregular operational state, or a critical operational state.

The nominal operational state generally corresponds to a desired operational state of the plasma 18, i.e. most or all state parameters of the plasma 18 are within a desired, nominal range.

The irregular operational state may correspond to an operational state wherein at least one state parameter or several operational parameters of the plasma 18 may be outside of the desired, nominal range. The irregular operational state may require tuning of parameters of the plasma control system 10, but the tuning of the parameters may not be time-critical. For example, the irregular operational state may comprise a non-optimal energy transfer into the plasma, a too low temperature, a too high temperature, a too low pressure, or a too high pressure.

The critical operational state may correspond to an operational state wherein at least one state parameter or several operational parameters of the plasma 18 may be outside of the desired, nominal range. The critical operational state may require timely tuning of parameters of the plasma control system 10, i.e. the tuning of the parameters may be time-critical. For example, the critical operational state may comprise an arc evolving in the plasma 18, or an arc already being present in the plasma 18. As another example, the critical operational state may comprise a breakdown of the plasma 18, which may require re-initiation of the plasma 18.

In an embodiment, the control circuit 22 may compare the first detector signal and/or the second detector signal with a comparison data set in order to detect the at least one operational state of the plasma 18. The comparison data set comprises, for example, previously measured first detector signals and/or previously measured second detector signals.

The comparison data set may comprise first detector signals and/or second detector signals that correspond to a nominal operational state of the plasma 18, an irregular operational state of the plasma 18, and/or a critical operational state of the plasma 18. In a particular example, the comparison data set may comprise first detector signals and/or second detector signals that correspond to an arc evolving or being present in the plasma 18.

In general, the mathematical model describes the plasma 18 in dependence of the RF signal applied to the plasma 18, i.e., in dependence of the output signal of the impedance matching network 20 applied to the chamber feed unit 14. The mathematical model allows for calculation of the operational parameters of the plasma 18 that are not measureable with currently available sensors, namely based on the first detector signal and based on the second detector signal, and optionally based on the at least one state parameter of the plasma 18 measured by the at least one plasma sensor 27 and/or based on the at least one state parameter of the RF generator circuit 12.

In an embodiment, the reference portion 40 of the RF signal serves as a reference signal for determining the operational parameters and thus for detecting the at least one operational state.

In an embodiment, as is shown in FIG. 5, the mathematical model describes a sheath 42 formed in the plasma in dependence of the RF signal 44 applied to the chamber feed unit 14. As is illustrated in FIG. 5, the sheath 42 oscillates over time, namely in dependence of a current amplitude and phase of the RF signal 44.

Diagrams 46, 48, 50 illustrate a voltage distribution of the sheath 42 in the plasma chamber for three different phases of the RF signal, labeled “1”, “2”, and “3”. These voltage distributions are obtained based on the mathematical model of the plasma 18.

Based on the at least one detected operational state, the control circuit controls the RF generator circuit 12 and/or the impedance matching network 20 (step S6).

If the detected operational state of the plasma 18 requires a change of the operational parameters of the RF generator circuit 12, the control circuit 22 may control the RF generator circuit 12 to adapts its operational parameters. For example, the control circuit 22 may control the RF generator circuit 12 to adapt at least one signal parameter of the RF signal generated.

In an embodiment, the at least one signal parameter may comprise an amplitude, a phase, a power level, a frequency, and/or a signal shape. However, it is to be understood that the at least one signal parameter may comprise any other suitable signal parameter.

As another example, the control circuit 22 may temporarily deactivate the RF generator circuit 12 if the at least one detected operational state comprises a critical operational state, for example at least one arc.

According to a further example, the control circuit 22 may control the impedance matching network 20 to adapt its impedance.

Summarizing, the plasma control system 10 and the plasma control method described above provide an optimized control of an operational state of the plasma 18. The operational state of the plasma 18 is detected based on the first detector signal and based on the second detector signal plugged into a mathematical model of the plasma 18. Depending on the operational state detected, the control circuit 22 appropriately controls the RF generator circuit 12 and/or the impedance matching network 20.

Certain embodiments disclosed herein include systems, apparatus, modules, units, devices, components, etc., that utilize circuitry (e.g., one or more circuits) in order to implement standards, protocols, methodologies or technologies disclosed herein, operably couple two or more components, generate information, process information, analyze information, generate signals, encode/decode signals, convert signals, transmit and/or receive signals, control other devices, etc. Circuitry of any type can be used. It will be appreciated that the term “information” can be use synonymously with the term “signals” in this paragraph. It will be further appreciated that the terms “circuitry,” “circuit,” “one or more circuits,” etc., can be used synonymously herein.

In an embodiment, circuitry includes, among other things, one or more computing devices such as a processor (e.g., a microprocessor), a central processing unit (CPU), a graphics processing unit (GPU), a digital signal processor (DSP), an application-specific integrated circuit (ASIC), a field programmable gate array (FPGA), a system on a chip (SoC), or the like, or any combinations thereof, and can include discrete digital or analog circuit elements or electronics, or combinations thereof. In an embodiment, circuitry includes hardware circuit implementations (e.g., implementations in analog circuitry, implementations in digital circuitry, and the like, and combinations thereof).

In an embodiment, circuitry includes combinations of circuits and computer program products having software or firmware instructions stored on one or more computer readable memories that work together to cause a device to perform one or more protocols, methodologies or technologies described herein. In an embodiment, circuitry includes circuits, such as, for example, microprocessors or portions of microprocessor, that require software, firmware, and the like for operation. In an embodiment, circuitry includes an implementation comprising one or more processors or portions thereof and accompanying software, firmware, hardware, and the like.

For example, the functionality described herein can be implemented by special purpose hardware-based computer systems or circuits, etc., or combinations of special purpose hardware and computer instructions. Each of these special purpose hardware-based computer systems or circuits, etc., or combinations of special purpose hardware circuits and computer instructions form specifically configured circuits, machines, apparatus, devices, etc., capable of implementing the functionality described herein.

Of course, in an embodiment, two or more of these components, or parts thereof, can be integrated or share hardware and/or software, circuitry, etc. In an embodiment, these components, or parts thereof, may be grouped in a single location or distributed over a wide area. In circumstances where the components are distributed, the components are accessible to each other via communication links.

In an embodiment, one or more of the components of the plasma control system 10, referenced above include circuitry programmed to carry out one or more steps of any of the methods disclosed herein. In an embodiment, one or more computer-readable media associated with or accessible by such circuitry contains computer readable instructions embodied thereon that, when executed by such circuitry, cause the component or circuity to perform one or more steps of any of the methods disclosed herein.

In an embodiment, the computer readable instructions includes applications, programs, program modules, scripts, source code, program code, object code, byte code, compiled code, interpreted code, machine code, executable instructions, and/or the like (also referred to herein as executable instructions, instructions for execution, program code, computer program instructions, and/or similar terms used herein interchangeably).

In an embodiment, computer-readable media is any medium that stores computer readable instructions, or other information non-transitorily and is directly or indirectly accessible by a computing device, such as processor circuitry, etc., or other circuity disclosed herein etc. In other words, a computer-readable medium is a non-transitory memory at which one or more computing devices can access instructions, codes, data, or other information. As a non-limiting example, a computer-readable medium may include a volatile random access memory (RAM), a persistent data store such as a hard disk drive or a solid-state drive, or a combination thereof. In an embodiment, memory can be integrated with a processor, separate from a processor, or external to a computing system.

Accordingly, blocks of the block diagrams and/or flowchart illustrations support various combinations for performing the specified functions, combinations of operations for performing the specified functions and program instructions for performing the specified functions. These computer program instructions may be loaded onto one or more computer or computing devices, such as special purpose computer(s) or computing device(s) or other programmable data processing apparatus(es) to produce a specifically-configured machine, such that the instructions which execute on one or more computer or computing devices or other programmable data processing apparatus implement the functions specified in the flowchart block or blocks and/or carry out the methods described herein. Again, it should also be understood that each block of the block diagrams and flowchart illustrations, and combinations of blocks in the block diagrams and/or flowchart illustrations, or portions thereof, could be implemented by special purpose hardware-based computer systems or circuits, etc., that perform the specified functions or operations, or combinations of special purpose hardware and computer instructions.

It will be appreciated that in one or more embodiments, the term computer or computing device can include, for example, any computing device or processing structure, including but not limited to a processor (e.g., a microprocessor), a central processing unit (CPU), a digital signal processor (DSP), an application-specific integrated circuit (ASIC), a field-programmable gate array (FPGA), a system on a chip (SoC), a graphics processing unit (GPU) or the like, or any combinations thereof.

In the foregoing description, specific details are set forth to provide a thorough understanding of representative embodiments of the present disclosure. It will be apparent to one skilled in the art, however, that the embodiments disclosed herein may be practiced without embodying all of the specific details. In some instances, well-known process steps have not been described in detail in order not to unnecessarily obscure various aspects of the present disclosure.

Although the method and various embodiments thereof have been described as performing sequential steps, the claimed subject matter is not intended to be so limited. As nonlimiting examples, the described steps need not be performed in the described sequence and/or not all steps are required to perform the method. Moreover, embodiments are contemplated in which various steps are performed in parallel, in series, and/or a combination thereof. As such, one of ordinary skill will appreciate that such examples are within the scope of the claimed embodiments.

In the detailed description herein, references to “one embodiment”, “an embodiment”, “an example embodiment”, “one or more embodiments”, “some embodiments”, etc., indicate that the embodiment or embodiments described may include a particular feature, structure, or characteristic, but every embodiment may not necessarily include the particular feature, structure, or characteristic. Moreover, such phrases are not necessarily referring to the same embodiment or embodiments. In addition, when a particular feature, structure, or characteristic is described in connection with an embodiment or embodiments, it is submitted that it is within the knowledge of one skilled in the art to affect such feature, structure, or characteristic in connection with other embodiments whether or not explicitly described. After reading the description, it will be apparent to one skilled in the relevant art(s) how to implement the disclosure in alternative embodiments. Thus, it will be appreciated that embodiments of the present disclosure may employ any combination of features described herein. All such combinations or sub-combinations of features are within the scope of the present disclosure.

Throughout this specification, terms of art may be used. These terms are to take on their ordinary meaning in the art from which they come, unless specifically defined herein or the context of their use would clearly suggest otherwise.

The drawings in the FIGURES are not to scale. Similar elements are generally denoted by similar references in the FIGURES. For the purposes of this disclosure, the same or similar elements may bear the same references. Furthermore, the presence of reference numbers or letters in the drawings cannot be considered limiting, even when such numbers or letters are indicated in the claims.

The present application may reference quantities and numbers. Unless specifically stated, such quantities and numbers are not to be considered restrictive, but exemplary of the possible quantities or numbers associated with the present application. Also in this regard, the present application may use the term “plurality” to reference a quantity or number. In this regard, the term “plurality” is meant to be any number that is more than one, for example, two, three, four, five, etc. The terms “about,” “approximately,” “near,” etc., mean plus or minus 5% of the stated value. For the purposes of the present disclosure, the phrase “at least one of A and B” is equivalent to “A and/or B” or vice versa, namely “A” alone, “B” alone or “A and B.”. Similarly, the phrase “at least one of A, B, and C,” for example, means (A), (B), (C), (A and B), (A and C), (B and C), or (A, B, and C), including all further possible permutations when greater than three elements are listed.

Where a range of values is provided, it is understood that each intervening value, to the tenth of the unit of the lower limit (unless the context clearly dictates otherwise), between the upper and lower limit of that range, and any other stated or intervening value in that stated range, is encompassed within the disclosure. The upper and lower limits of these smaller ranges may independently be included in the smaller ranges and are also encompassed within the disclosure, subject to any specifically excluded limit in the stated range. While the stated range includes one or both of the limits, ranges excluding either or both of those included limits are also included in the disclosure

The principles, representative embodiments, and modes of operation of the present disclosure have been described in the foregoing description. However, aspects of the present disclosure which are intended to be protected are not to be construed as limited to the particular embodiments disclosed. Further, the embodiments described herein are to be regarded as illustrative rather than restrictive. It will be appreciated that variations and changes may be made by others, and equivalents employed, without departing from the spirit of the present disclosure. Accordingly, it is expressly intended that all such variations, changes, and equivalents fall within the spirit and scope of the present disclosure, as claimed.

The embodiments of the invention in which an exclusive property or privilege is claimed are defined as follows:

1. A plasma control system, the plasma control system comprising an impedance matching network, a radio frequency, RF, generator circuit, a chamber feed unit, and a control circuit,
wherein the RF generator circuit is configured to generate an RF signal,
wherein the chamber feed unit is configured to feed energy into plasma,
wherein an input port of the impedance matching network is connected to the RF generator circuit, and wherein an output port of the impedance matching network is connected to the chamber feed unit,
wherein the plasma control system further comprises a first detector circuit that is arranged between the RF generator circuit and the impedance matching network, wherein an RF output of the first detector circuit is connected to the impedance matching network,
wherein the first detector circuit is configured to generate a first detector signal associated with the RF signal upstream of the impedance matching network,
wherein the plasma control system further comprises a second detector circuit, wherein the second detector circuit is arranged between the impedance matching network and the chamber feed unit,
wherein the second detector circuit is configured to generate a second detector signal associated with the RF signal downstream of the impedance matching network,
wherein the control circuit is configured to detect at least one operational state of the plasma based on the first detector signal, based on the second detector signal, and based on a mathematical model of the plasma.

2. The plasma control system of claim 1, wherein the control circuit is configured to detect at least one arc evolving in the plasma based on the first detector signal, based on the second detector signal, and based on the mathematical model of the plasma.

3. The plasma control system of claim 1, wherein the first detector circuit comprises a coupling circuit.

4. The plasma control system of claim 1, wherein the second detector circuit comprises a measurement probe.

5. The plasma control system of claim 1, wherein the first detector signal comprises an amplitude of a first RF voltage associated with the RF signal upstream of the impedance matching network, an amplitude of a first RF current associated with the RF signal upstream of the impedance matching network, and a phase between the first RF voltage and the first RF current.

6. The plasma control system of claim 1, wherein the second detector signal comprises an amplitude of a second RF voltage associated with the RF signal downstream of the impedance matching network, an amplitude of a second RF current associated with the RF signal downstream of the impedance matching network, and a phase between the second RF voltage and the second RF current.

7. The plasma control system of claim 1, wherein the control circuit is configured to control the RF generator circuit based on the at least one detected operational state.

8. The plasma control system of claim 7, wherein the control circuit is configured to control the RF generator circuit to adapt at least one signal parameter of the RF signal generated.

9. The plasma control system of claim 7, wherein the control circuit is configured to temporarily deactivate the RF generator circuit if the at least one detected operational state comprises at least one arc.

10. The plasma control system of claim 1, wherein the control circuit is configured to control the impedance matching network based on the at least one detected operational state.

11. The plasma control system of claim 10, wherein the control circuit is configured to control the impedance matching network to adapt its impedance.

12. The plasma control system of claim 1, wherein the mathematical model describes a sheath in the plasma.

13. The plasma control system of claim 12, wherein the mathematical model describes the sheath in the plasma in dependence of the RF signal fed into the plasma by the chamber feed unit.

14. The plasma control system of claim 1, wherein the control circuit is configured to compare the first detector signal and/or the second detector signal with a comparison data set in order to detect the at least one operational state of the plasma, the comparison data set comprising previously measured first detector signals and/or previously measured second detector signals.

15. The plasma control system of claim 1, wherein the RF signal generated by the RF generator circuit comprises a power portion and a reference portion, wherein the reference portion is modulated onto the power portion, and wherein the power portion and the reference portion have frequencies being different from each other.

16. The plasma control system of claim 1, wherein the control circuit comprises a field-programmable gate array, FPGA.

17. The plasma control system of claim 1, wherein the plasma control system comprises at least one plasma sensor, wherein the at least one plasma sensor is configured to measure at least one state parameter of the plasma, and wherein the control circuit is configured to detect the at least one operational state of the plasma based on the at least one state parameter of the plasma.

18. The plasma control system of claim 1, wherein the RF generator circuit is configured to provide at least one state parameter of the RF generator circuit, and wherein the control circuit is configured to detect the at least one operational state of the plasma based on the at least one state parameter of the RF generator circuit.

19. A plasma control method, the plasma control method comprising:
generating, by an RF generator circuit, at least one RF signal;
processing, by at least one impedance matching network, the at least one RF signal, thereby obtaining at least one output signal;
feeding the at least one output signal to at least one chamber feed unit;
generating, by a first detector circuit being arranged between the between the RF generator circuit and the impedance matching network, a first detector signal associated with the RF signal upstream of the impedance matching network;
generating, by a second detector circuit being arranged between the impedance matching network and the chamber feed unit, a second detector signal associated with the RF signal downstream of the impedance matching network; and
detecting, by a control circuit, at least one operational state of the plasma based on the first detector signal, based on the second detector signal, and based on a mathematical model of the plasma.

20. The plasma control method of claim 19, wherein at least one arc evolving in the plasma is detected based on the first detector signal, based on the second detector signal, and based on the mathematical model of the plasma.
